(19) United States
(12) Patent Application Publication
(10) Pub. No.: US 2002/0048896 A1
(43) Pub. Date: Apr. 25, 2002

(54) Method of fabricating isolation trenches in a semiconductor substrate

(75) Inventor: Horng-Huei Tseng, Hsinchu (TW)

Correspondence Address: INTELLECTUAL PROPERTY SOLUTIONS, PLLC, 1300 PENNSYLVANIA AVE N.W., SUITE 700, WASHINGTON, DC, 20004, US

(73) Assignee: Vanguard International Semiconductor Corporation

(21) Appl. No.: 09/761,887

(22) Filed: Jan. 17, 2001

(30) Foreign Application Priority Data
Jul. 11, 2000 (TW) 89113738

(51) Int. Cl. H01L 21/76

(52) U.S. Cl. 438/424

(57) ABSTRACT

A method of fabricating isolation trenches in a semiconductor. The width of an isolation trench (FIGS. 6 and 7) is defined by the width between a field oxide layer (104) and a pad oxide layer (101a), whereby the size of the isolation trench is effectively reduced.

### BACKGROUND OF THE INVENTION

1. Field of the Invention

The present invention relates in general to a method of fabricating semiconductor device. More specifically, it relates to a method of fabricating isolation trenches in a semiconductor substrate.

2. Description of the Related Art

To improve the density of integrated circuit devices requires reduction of the sizes of the transistors used in the devices. To reduce the sizes of the transistors, reducing the area of the active regions in the integrated circuit is required. In addition, it is generally desirable to reduce the area of the device isolation regions used to separate the active regions of the integrated circuit.

Field oxide layers formed by using local oxidization of silicon (LOCOS) always serve as the device isolation regions for isolating devices in the integrated circuit. However, the so called “bird's peak” may be produced at the edges of the active regions which may encroach on and narrow the active regions.

Isolation trenches have been widely used as device isolation regions in the integrated circuit. The following steps form an isolation trench. First, a photolithographic mask is used to define the boundaries of trenches on a substrate surface surrounding active regions and trenches that are etched into the substrate according to the mask. The trenches are then filled with an insulting material such as a deposited silicon dioxide to form device isolation regions. To reduce separation between active regions, the trenches generally must be very narrow. However, the narrowness of trenches tends to be limited by the resolution of the available photolithography techniques. Therefore, it is generally difficult to reliably produce a sufficiently narrow isolation trench.

### SUMMARY OF THE INVENTION

Therefore, an object of the present invention is to provide a method of fabricating isolation trenches in a semiconductor substrate, therefore effectively reducing the size of the isolation trenches.

The other object of the present invention is to provide a method of fabricating isolation trenches in a semiconductor substrate to reliably produce isolation trenches narrower than that defined by using conventional photolithography techniques.

The present invention achieves the above-indicated objects by providing a method of fabricating isolation trenches in a semiconductor substrate. The method comprises the following steps.

First, (a) a first isolation layer is formed on the semiconductor substrate; (b) a mask layer is then formed on said first isolation layer; wherein the first isolation layer is a pad oxide layer and the mask layer is made of a nitride layer.

Then, (c) portions of the first isolation layer adjacent and underlying edge portions of the mask layer is removed, thereby undermining edge portions of the mask layer and leaving a portion of the first isolation layer underlying the mask layer.

Next, (d) a second isolation layer (for example, a nitride layer) is formed over the semiconductor substrate and the mask layer, and beneath undermined portions of the mask layer and adjacent to the remaining portion of the first isolation layer.

Then, (e) portions of the second isolation layer are removed to form spacers adjacent to the mask layer. (f) Isolation regions are formed adjacent to the spacers, in said semiconductor substrate; wherein the isolation regions are field oxide layers formed by using local oxidization method.

Next, (g)the spacers and said mask layer are removed (for example, using wet etching) to expose the remaining portion of the first isolation layer and the semiconductor substrate. Finally, (h) portions of the semiconductor substrate are removed to form isolation trenches between the remaining portion of the first isolation layer and the isolation regions, wherein the isolation trenches extends into the semiconductor substrate.

Furthermore, after completing the step (f), an etching process is carried out to remove the spacers, the mask layer, and portions of the semiconductor substrate between the remaining portion of the first isolation layer and the isolation regions, thereby forming isolation trenches deep into the semiconductor substrate.

### BRIEF DESCRIPTION OF THE DRAWINGS

The following detailed description, given by way of example and not intended to limit the invention solely to the embodiments described herein, will best be understood in conjunction with the accompanying drawings, in which:

FIGS. 1 to 8 show, in cross-sectional view, the fabricating process of a preferred embodiment according to the present invention.

### DETAILED DESCRIPTION OF THE PREFERRED EMBODIMENTS

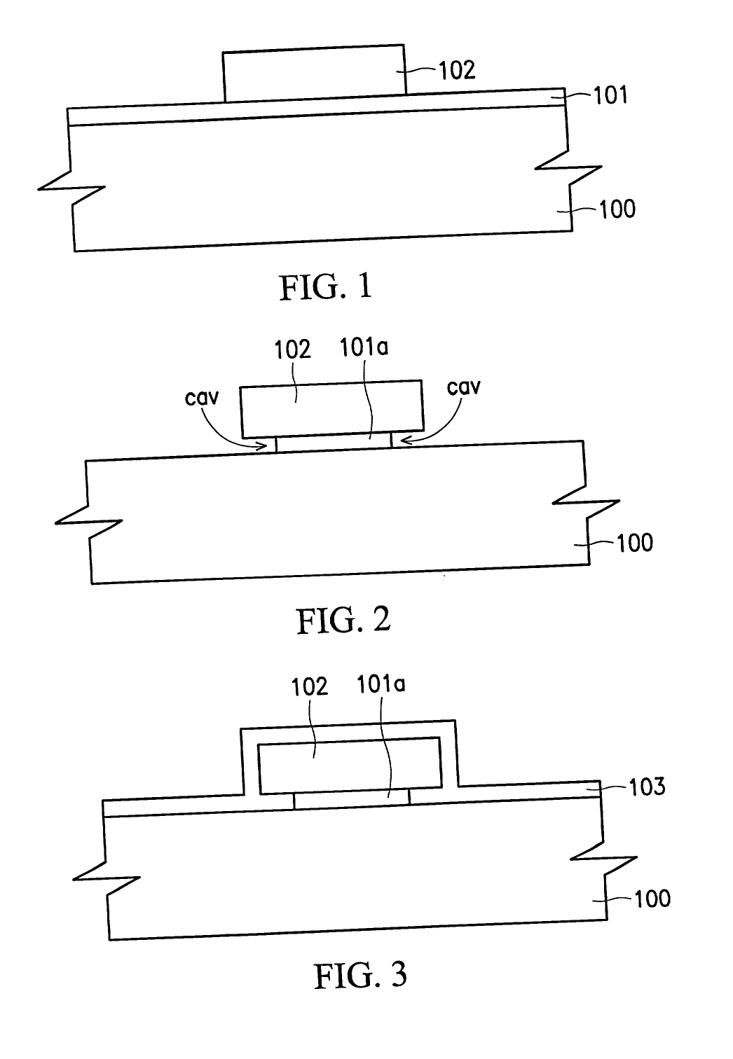

According to the present invention, the process of fabricating isolation trenches in a semiconductor substrate is shown in FIGS. 1 to 8 in cross-sectional view.

First, a first isolation layer 101 is formed on a semiconductor substrate 100. Then, a mask layer 102 is formed on the first isolation layer 101, as depicted in FIG. 1. The steps of forming the mask layer 102 comprise: forming a third isolation layer on the first isolation layer 101; and then patterning and etching the third isolation layer thereby forming the mask layer 102. In this embodiment, the first isolation layer 101 is a pad oxide layer; the third isolation layer is a nitride layer.

Then, portions of the first isolation layer 101 adjacent and underlying edge portions of the mask layer 102 are removed, thereby undermining edge portions of the mask layer 102 and leaving a portion of the first isolation layer 101a underlying the mask layer 102, forming two undermined regions (cav) adjacent to the remaining first isolation layer 101a; as shown in FIG. 2.

A second isolation layer 103 is formed over the semiconductor substrate 100 and the mask layer 102, and beneath undermined portions of the mask layer 102 (i.e. filled in the two undermined regions (cav)) and adjacent to the remaining portion of the first isolation layer 101a; as shown in FIG. 3. In this embodiment, the second isolation layer 103 is a nitride layer.

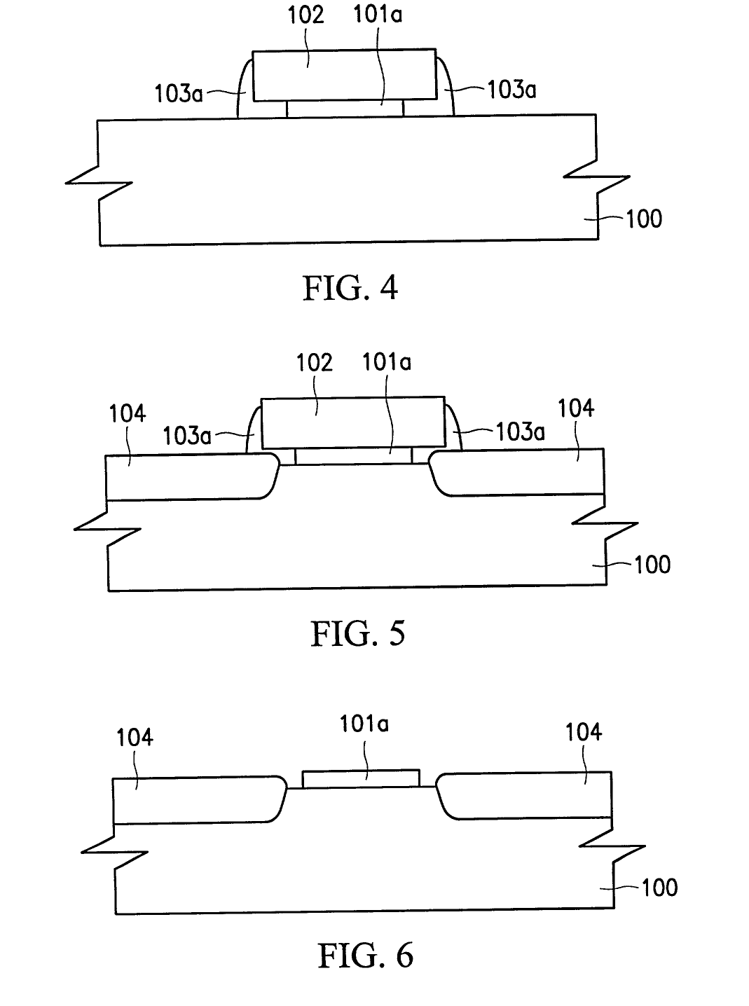

Then, portions of the second isolation layer 103 are removed by carrying out anisotropic etching to form spacers 103a adjacent to the mask layer 102, and expose the semiconductor substrate 100; as shown in FIG. 4.

Next, isolation regions 104 are formed adjacent to the spacers 103a, in the semiconductor substrate 100; as shown in FIG. 5. For example, the isolation regions 104 are field oxide layers formed by selectively oxidizing the semiconductor substrate 100 (by using LOCOS method).

Further, the spacers 103a and the mask layer 102 are removed by wet etching to expose the remaining portion of the first isolation layer 101a and the semiconductor substrate 100; as shown in FIG. 6. In this embodiment, the solvent used for wet etching is H₃PO₄.

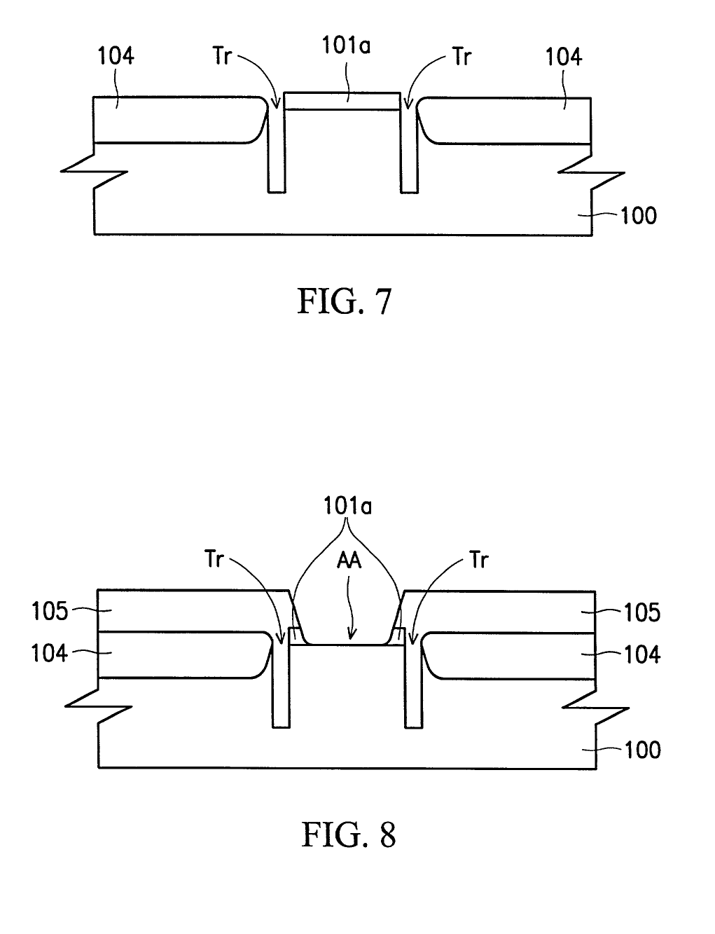

Then, portions of the semiconductor substrate 100 are etched to form isolation trenches (Tr) between the remaining portion of the first isolation layer 101a and the isolation regions 104, and the isolation trenches (Tr) extends into the semiconductor substrate 100; as shown in FIG. 7.

After completing the step as described in FIG. 5, alternative steps can be taken to finish the fabricating process. After forming isolation regions 104, the spacers 103a, the mask layer 102, and portions of the semiconductor substrate 100 between the remaining portion of the first isolation layer 101a and the isolation regions 104 are directly removed, thereby forming isolation trenches (Tr) deep into the semiconductor substrate 100; as shown in FIG. 7.

Furthermore, a fourth isolation layer 105 is formed over the semiconductor substrate 100, filling the isolation trenches (Tr). In this embodiment, the fourth isolation layer 105 is an oxide layer (SiO₂). Then, the fourth isolation layer 105 (SiO₂) and the remaining portion of the first isolation layer 101a (pad oxide) are patterned and etched to form an open region AA, exposing the semiconductor substrate 100 which serves as an active region.

From the above descriptions, it is obvious that the width of a isolation trench (Tr) is defined by the width between the isolation region 104 and the remaining portion of the first isolation layer 101a, therefore the size of the isolation trench can be effectively reduced and is narrower than that defined by using conventional photolithography techniques.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of fabricating isolation trenches in a semiconductor substrate, the method comprising:
forming a first isolation layer on said semiconductor substrate;
forming a mask layer on said first isolation layer;
removing portions of said first isolation layer adjacent and underlying edge portions of said mask layer, thereby undermining edge portions of said mask layer and leaving a portion of said first isolation layer underlying said mask layer;
forming a second isolation layer over said semiconductor substrate and said mask layer, and beneath undermined portions of said mask layer and adjacent to the remaining portions of said first isolation layer;
removing portions of said second isolation layer to form spacers adjacent to said mask layer;
forming isolation regions adjacent to said spacers, in said semiconductor substrate;
removing said spacers and said mask layer to expose the remaining portions of said first isolation layer and said semiconductor substrate; and
removing portions of said semiconductor substrate to form isolation trenches between the remaining portions of said first isolation layer and said isolation regions, said isolation trenches extending into said semiconductor substrate.

2. The method as claimed in claim 1, wherein forming said mask layer comprises the steps of:
forming a third isolation layer on said first isolation layer; and
patterning and etching said third isolation layer thereby forming said mask layer.

3. The method as claimed in claim 2, wherein said first isolation layer is a pad oxide layer; said second and third isolation layers are nitride layers; and said isolation regions are field oxide layers.

4. The method as claimed in claim 3, wherein said spacers and said mask layer are removed by wet etching.

5. The method as claimed in claim 3, wherein said field oxide layers are formed by selectively oxidizing said semiconductor substrate.

6. The method as claimed in claim 1, further filling said isolation trenches with fourth isolation layers.

7. The method as claimed in claim 6, wherein said fourth isolation layers are oxide layers.

8. A method of fabricating isolation trenches in a semiconductor substrate, the method comprising:
forming a first isolation layer on said semiconductor substrate;
forming a mask layer on said first isolation layer;
removing portions of said first isolation layer adjacent and underlying edge portions of said mask layer, thereby undermining edge portions of said mask layer and leaving a portion of said first isolation layer underlying said mask layer;
forming a second isolation layer over said semiconductor substrate and said mask layer, and beneath undermined portions of said mask layer and adjacent to the remaining portions of said first isolation layer;
removing portions of said second isolation layer to form spacers adjacent to said mask layer;
forming isolation regions adjacent to said spacers, in said semiconductor substrate;
removing said spacers, said mask layer, and portions of said semiconductor substrate between the remaining portions of said first isolation layer and said isolation regions thereby forming isolation trenches deep into said semiconductor substrate.

9. The method as claimed in claim 8, wherein forming said mask layer comprises the steps of:
forming a third isolation layer on said first isolation layer; and
patterning and etching said third isolation layer thereby forming said mask layer.

10. The method as claimed in claim 9, wherein said first isolation layer is a pad oxide layer; said second and third isolation layers are nitride layers; and said isolation regions are field oxide layers.

11. The method as claimed in claim 10, wherein said field oxide layers are formed by selectively oxidizing said semiconductor substrate.

12. The method as claimed in claim 8, further filling said isolation trenches with fourth isolation layers.

13. The method as claimed in claim 12, wherein said fourth isolation layers are oxide layers.
